(19) United States
(12) Patent Application Publication
(10) Pub. No.: US 2026/0324328 A1
(43) Pub. Date: Oct. 15, 2026

(54) CONTEMPORANEOUS ETCHING OF OXIDE AND DEPOSITION OF METAL-CONTAINING SUBSTANCE ON PATTERNING MASK

(71) Applicant: Lam Research Corporation, Fremont, CA (US)

(72) Inventors: Wenbing YANG, Campbell, CA (US); Pei LIU, Fremont, CA (US); Pankaj Ghanshyam RAMNANI, Pleasanton, CA (US); Arunima Deya BALAN, Mountain View, CA (US); Yiwen FAN, Fremont, CA (US); Samantha SiamHwa TAN, Newark, CA (US); Yang PAN, Los Altos, CA (US)

(21) Appl. No.: 19/485,762

(22) PCT Filed: Jun. 7, 2024
(86) PCT No.: PCT/US2024/033146

§ 371 Date: Nov. 19, 2025

Related U.S. Application Data
(60) Provisional application No. 63/507,420, filed on Jun. 9, 2023.

(51) Int. Cl. H10P 50/00; H01J 37/32; H10P 50/28; H10P 70/00

(52) U.S. Cl. CPC H10P 50/73; H01J 37/32449; H10P 50/283; H10P 50/285; H10P 70/23; H01J 2237/334

(57) ABSTRACT

A method of etching a feature in an oxide layer formed on a substrate comprises introducing a gas mixture comprising an etching agent and a metal halide into a plasma formed in a processing chamber in which a substrate is located. The substrate comprises an oxide layer partially covered with a patterning mask. The method further comprises contemporaneously etching the feature in an unmasked portion of the oxide layer and depositing a substance containing a metal from the metal halide on the patterning mask.

### BACKGROUND

Pattern transfer processes are commonly used in manufacturing integrated electronic devices. Some pattern transfer processes utilize photolithography to create a pattern in a photoresist layer. In some such processes, a photoresist is patterned to selectively cover or expose different portions of a hard mask layer deposited on an underlying material. A preliminary etch process transfers the pattern from the photoresist to the hard mask layer by etching through the exposed portions of the hard mask layer. Another etch process transfers the pattern in the hard mask layer to the underlying material.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to performing a contemporaneous etching of an oxide and deposition of a substance containing a metal onto a patterning mask. One example provides a method of etching a feature in an oxide layer on a substrate. The method comprises introducing a gas mixture comprising an etching agent and a metal halide into a plasma formed in a processing chamber in which the substrate is located. The substrate comprises a patterning mask partially covering the oxide layer. The method further comprises contemporaneously etching the feature in an unmasked portion of the oxide layer and depositing a substance containing a metal from the metal halide on the patterning mask.

In some such examples, the etching agent comprises a fluorocarbon.

Alternatively or additionally, in some such examples, the etching agent comprises hydrogen fluoride.

Alternatively or additionally, in some such examples, the oxide layer comprises a metal oxide or a metalloid oxide.

Alternatively or additionally, in some such examples, the oxide layer comprises silicon dioxide or titanium dioxide.

Alternatively or additionally, in some such examples, the patterning mask comprises one or more of a metal oxide, amorphous carbon, boron-doped carbon, tungsten-doped carbon, titanium nitride, silicon, silicon nitride, silicon carbide, silicon carbonitride, photoresist materials, or a polymer.

Alternatively or additionally, in some such examples, the metal halide comprises a halide of one or more of silicon, germanium, tin, titanium, zirconium, hafnium, vanadium, niobium, tantalum, boron, aluminum, gallium, indium, iron, ruthenium, rhenium, antimony, tungsten, molybdenum, or bismuth.

Alternatively or additionally, in some such examples, the metal halide comprises one or more of tungsten hexafluoride or molybdenum hexafluoride.

Alternatively or additionally, in some such examples, the metal halide comprises an oxyhalide.

Another example provides a structure comprising a substrate. An oxide layer covers at least a portion of the substrate. A patterning mask partially covers the oxide layer. A substance containing a metal from a metal halide is deposited on the patterning mask.

In some such examples, the oxide layer comprises a metal oxide or a metalloid oxide.

Alternatively or additionally, in some such examples, the oxide layer comprises silicon dioxide or titanium dioxide.

Alternatively or additionally, in some such examples, the patterning mask comprises one or more of a metal oxide, amorphous carbon, boron-doped carbon, tungsten-doped carbon, titanium nitride, silicon, silicon nitride, silicon carbide, silicon carbonitride, or a polymer.

Alternatively or additionally, in some such examples, the metal halide comprises a halide of one or more of silicon, germanium, tin, titanium, zirconium, hafnium, vanadium, niobium, tantalum, boron, aluminum, gallium, indium, iron, ruthenium, rhenium, antimony, tungsten, molybdenum, or bismuth.

Alternatively or additionally, in some such examples, the metal halide comprises an oxyhalide.

Another example provides a processing tool. The processing tool comprises a processing chamber. The processing tool further comprises a plasma generator configured to generate a plasma in the processing chamber. The processing tool further comprises a substrate holder positioned within the processing chamber. The processing tool further comprises flow control hardware configured to control a flow of each of one or more processing chemicals into the processing chamber. The processing tool further comprises a controller. The controller is configured to control the flow control hardware to introduce a gas mixture comprising an etching agent and a metal halide into the processing chamber. The controller is further configured to control the plasma generator to generate the plasma in the processing chamber, wherein the gas mixture and the plasma are configured to etch an unmasked oxide layer on a substrate and contemporaneously deposit a substance containing a metal from the metal halide on a masked portion of the substrate comprising a patterning mask that covers a portion of the oxide layer.

Alternatively or additionally, in some such examples, the processing tool comprises an etching chemical source, wherein the etching chemical source comprises a fluorocarbon.

Alternatively or additionally, in some such examples, the processing tool comprises an etching chemical source, wherein the etching chemical source comprises hydrogen fluoride.

Alternatively or additionally, in some such examples, the processing tool comprises a metal halide source, wherein the metal halide source comprises a halide of one or more of silicon, germanium, tin, titanium, zirconium, hafnium, vanadium, niobium, tantalum, boron, aluminum, gallium, indium, iron, ruthenium, rhenium, antimony, tungsten, molybdenum, or bismuth.

Alternatively or additionally, in some such examples, the metal halide source comprises an oxyhalide.

Another example provides a method of removing patterning mask remnants from a substrate between a resist development process and an etching process. The method comprises introducing a metal halide into a plasma formed in a processing chamber in which the substrate is located, the substrate comprising a photoresist patterning mask and patterning mask remnants, to deposit a substance containing a metal from the metal halide at least on the photoresist patterning mask to protect the photoresist patterning mask during removal of the patterning mask remnants.

In some such examples, the patterning mask comprises a metal oxide photoresist.

Alternatively or additionally, in some such examples, removal of the patterning mask remnants and deposition of the substance containing a metal from the metal halide occurs contemporaneously.

Alternatively or additionally, in some such examples, the deposition of the substance containing a metal from the metal halide and the removal of the patterning mask remnants occurs sequentially.

Alternatively or additionally, in some such examples, the patterning mask comprises a polymer-based photoresist.

Alternatively or additionally, in some such examples, deposition of the substance containing a metal from the metal halide further occurs both before and contemporaneously with the removal of patterning mask remnants.

### BRIEF DESCRIPTION OF THE DRAWINGS

FIG. 1 shows a schematic diagram of an example processing tool configured to etch a substrate.

FIG. 2 shows a top-down view of the substrate of FIG. 1.

FIGS. 3A-3C show a cross-sectional view of the substrate of FIG. 1, and illustrate the contemporaneous etching of an oxide layer and deposition of a substance containing a metal on a patterning mask.

FIGS. 4A-4B show a cross-sectional view of another example substrate and illustrate contemporaneous etching of an oxide layer and deposition of a substance containing a metal on a photoresist material.

FIG. 5 shows a flow diagram depicting an example method for etching a feature in an oxide layer formed on a substrate.

FIGS. 6A-6C show a cross-sectional view of another example substrate, and illustrate contemporaneous removal of photoresist mask remnants and deposition of a substance containing a metal on a patterned photoresist.

FIG. 7 shows a flow diagram depicting an example method for performing removal of photoresist mask remnants.

FIG. 8 shows a flow diagram depicting another example method for performing removal of photoresist mask remnants.

FIG. 9 shows a schematic diagram of an example computing system.

### DETAILED DESCRIPTION

The term “contemporaneous” generally represents two or more events that at least partially overlap in time.

The term “etching” generally represents a chemical process by which material is removed from a substrate.

The term “etching agent” generally represents a chemical substance used to remove materials from a substrate. An etching agent can be added to a plasma to produce reactive species to chemically react with and volatilize a surface of the substrate. Example etching agents include various chlorine-containing materials and fluorine-containing materials. Examples of chlorine-containing etching agents include molecular chlorine (Cl₂), nitrogen trichloride (NCl₃) boron trichloride (BCl₃), sulfur hexachloride (SCl₆), tetrachloromethane (CCl₄), hydrogen chloride (HCl), and chlorinated compounds having a general formula CₐH_{b}Cl_{c}, where a=1-10. Examples of fluorine-containing etching agents include molecular fluorine (F₂), nitrogen trifluoride (NF₃), boron trifluoride (BF₃), sulfur hexafluoride (SF₆), tetrafluoromethane (CF₄), hydrogen fluoride (HF), and fluorocarbon compounds having a general formula CₐH_{b}F_{c}, where a=1-10.

The term “flow control hardware” generally represents components configured to place one or more processing chemical sources in fluid connection with a processing chamber. Flow control hardware can comprise one or more mass flow controllers and/or valves, for example. Example chemical sources include etching chemical sources and metal halide sources.

The term “fluid communication” generally represents a structural configuration that enables a fluid substance, such as a liquid or gas, to flow from one location to another.

The term “fluorocarbon” generally represents a molecule comprising one or more carbon atoms and one or more fluorine atoms. Examples of fluorocarbons include fluoroethane (C₂H₅F), 1,1-difluoroethane (C₂H₄F₂), fluoromethane (CH₃F), difluoromethane (CH₂F₂), trifluoromethane (CHF₃), and tetrafluoromethane (CF₄).

The term “mask remnants” generally represents photoresist material left behind on a substrate after development of the photoresist. The term “scum” also can be used to refer to mask remnants.

The term “metal halide” generally represents compounds comprising a metal and a halogen. Examples of metal halides include tungsten hexafluoride (WF₆) and molybdenum hexafluoride (MoF₆).

The term “oxide layer” generally represents a layer of material deposited on a substrate surface that comprises oxygen and an oxidized species. Examples of oxide layers comprise doped or undoped layers of silicon dioxide (SiO₂), silicon oxynitride (SiOₓN_{y}, 0≤x≤2, 0≤y≤1.33), silicon oxycarbide (SiCₓO₂₍₁₋ₓ₎ (0≤x≤1)), and metal oxides. Example metal oxides include hafnium oxide (HfOₓ), titanium oxide (TiOₓ), tungsten oxide (WOₓ), tin oxide (SnOₓ), and molybdenum oxide (MoOₓ).

The term “oxyhalide” generally represents compounds comprising an oxygen atom and a halogen atom. Examples of oxyhalides include tungsten oxytetrafluoride (WOF₄), tungsten oxytetrachloride (WOCl₄), molybdenum oxytetrafluoride (MoOF₄), and molybdenum oxytetrachloride (MoOCl₄).

The term “patterning mask” generally represents a film that protects an underlying material from etching. Examples of patterning mask materials include metal oxides (e.g. for extreme ultraviolet (EUV) photolithography), amorphous carbon, boron-doped carbon, tungsten-doped carbon, titanium nitride (TiN), silicon (Si), silicon nitride (Si₃N₄), silicon carbide (SiC), silicon carbonitride (xSi₃N₄·(1−x)SiC), and polymer films (e.g. polymer photoresists).

The term “plasma” generally represents a gas comprising cations and free electrons.

The term “plasma generator” generally represents a device configured to generate a plasma to provide reactive species and/or energetic ions for substrate processing in a processing chamber.

The term “processing chamber” generally represents an enclosure in which chemical and/or physical processes are performed on substrates. The pressure, temperature and atmospheric composition within a processing chamber are controllable to perform chemical and/or physical processes.

The term “processing tool” generally represents a machine including a processing chamber and other hardware configured to enable processing to be carried out in the processing chamber.

The term “substrate” generally represents any object on which material can be deposited or from which material can be removed by etching.

The term “substrate holder” generally represents any structure configured to support a substrate in a processing chamber. Examples comprise chucks, pedestals, and showerhead pedestals used for backside deposition processes.

The term “unmasked portion” generally represents a portion of a substrate that is not covered by a patterned mask.

As introduced above, pattern transfer processes are commonly used in semiconductor device fabrication. Pattern transfer processes utilize patterning masks, such as photoresist masks and hard masks, to transfer patterns to underlying material layers. For example, photolithography can be used to create a pattern on a substrate for transfer to another layer on the substrate using a photoresist. A photoresist is a polymer material that changes properties when exposed to light. In a photoresist patterning process, a photoresist layer is deposited on a substrate. The photoresist layer is then exposed to a pattern of light. In some examples, the photoresist layer degrades when exposed to the light. The light-exposed portion of the photoresist layer can then be removed, leaving the unexposed portion of the photoresist layer on the substrate. In other examples, the photoresist layer hardens when exposed to the light. The unexposed portion of the photoresist layer can then be removed. In either case, a patterned film can be formed by selectively exposing portions of the photoresist layer to light.

Photolithography can be used to form a pattern in a hard mask layer. A hard mask layer is a layer of material with a higher selectivity to an etching process than a polymer photoresist. In such a process, a photoresist layer is deposited onto a hard mask layer. Then, the photoresist is patterned. This exposes some portions of the hard mask layer while leaving other portions of the hard mask layer covered with photoresist. Next, a preliminary etching process is used to remove material from the exposed portions of the hard mask layer. This transfers the pattern from the photoresist to the hard mask layer. Another etching process transfers the pattern from the hard mask layer to a layer that underlies the hard mask layer.

However, technical challenges exist in preserving fidelity of pattern features transferred from a photoresist to a hard mask layer, and from the hard mask layer to an underlying layer. For example, photoresist scum can lead to bridging defects. In some instances, a de-scum step is applied to prevent such defects. However, the de-scum step can reduce the thickness of the photoresist layer, which can induce line breakage.

Etching the underlying layer also consumes the hard mask layer. The use of too thin of a hard mask can result in manufacturing defects, such as line breakage. Local contact dimension (CD) and height variation can generate weak points of reduced CD and height, where mask consumption can be enhanced that induces line breakage type defects. The degradation of the hard mask layer can also pose a challenge for integration with other processing steps, such as chemical-mechanical polishing (CMP), which can demand retention of a portion of the hard mask layer thickness.

To address these issues, a thicker hard mask layer can be used. However, increasing the thickness of the hard mask layer can lead to other issues, such as line roughness and deviation (“wiggling”) caused by variability in the hard mask. Also, a thick carbon layer etch can induce excessive roughness due to polymer deposition on a sidewall of the hard mask during the etch process.

Accordingly, examples are disclosed that relate to an etching process that selectively deposits a substance on a patterning mask, such as a hard mask or photoresist mask (for example, a polymer photoresist or an extreme ultraviolet (EUV) photoresist, such as a metal oxide photoresist), to help avoid consumption of the patterning mask in the etching process. Briefly, a gas mixture comprising an etching agent and a metal halide is introduced into a processing chamber in which a substrate is located. The substrate comprises an oxide layer (e.g. SiO₂) partially covered with a patterning mask. A feature is etched in an unmasked portion of the oxide layer. A substance containing a metal from the metal halide is contemporaneously deposited on the patterning mask. This process selectively deposits an additive material on a hard mask layer in situ while a target material is etched spontaneously. The deposition of the additive material can maintain or increase a thickness of the patterning mask during the etching process. As a result, the disclosed examples can more faithfully preserve pattern features during pattern transfer than an etching process that omits the contemporaneous deposition of the substance containing the metal. This can help to prevent defects such as line breakage, line roughness, and wiggling. In some examples, this process enables the thickness of the hard mask layer to be reduced from 30 nm to 5 nm while preserving pattern transfer integrity and preventing etch-induced defects. This also allows the use of a thinner hard mask layer than an etching process that omits the contemporaneous deposition of the substance containing the metal, which obviates the tradeoff between bridging and breakage.

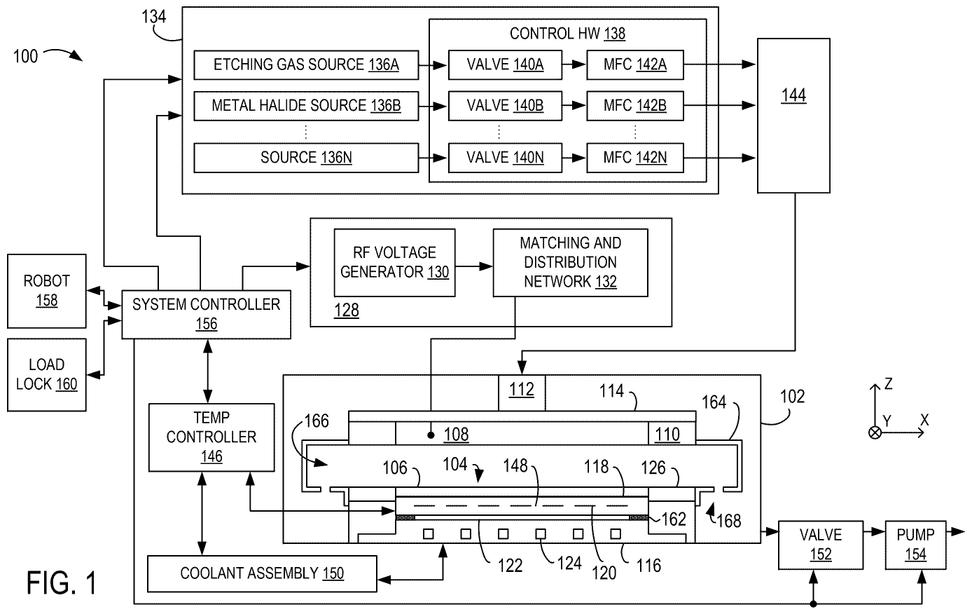

Prior to discussing these examples in more detail, FIG. 1 schematically shows an example processing tool 100 in the form of a plasma etching tool. Processing tool 100 includes a processing chamber 102. Processing tool 100 further includes a substrate holder 104 positioned within the processing chamber 102. During operation, a substrate 106 is arranged on the substrate holder 104. In some examples, the substrate holder 104 includes a pedestal, an electrostatic chuck, and/or any other suitable components for supporting the substrate 106.

The processing tool 100 further comprises an inner electrode 108 and an outer electrode 110. The use of separate components for inner electrode 108 and outer electrode 110 instead of a unitary, larger electrode allows inner electrode 108 and outer electrode 110 to be replaced at different frequencies, for example.

In the depicted example, inner electrode 108 and outer electrode 110 are incorporated in a showerhead 112 configured to introduce and distribute process chemicals. Example process chemicals include an etching agent for chemical etching, a metal halide for deposition, and an inert gas for use as a diluent gas, a purge gas, and/or a sputtering gas. A substrate-facing surface of showerhead 112 includes a plurality of holes through which the process chemicals flow.

The processing tool 100 further comprises an electrode heater 114 arranged above inner electrode 108 and outer electrode 110. Electrode heater 114 is thermally coupled to inner electrode 108 and outer electrode 110. Electrode heater 114 is used to control a temperature of inner electrode 108 and/or outer electrode 110 during substrate processing.

The substrate holder 104 includes a conductive baseplate 116 that acts as a lower electrode. The conductive baseplate 116 supports a substrate heater 120. In some examples, the substrate heater 120 takes the form of a ceramic layer. In some more specific examples, the substrate heater 120 comprises a ceramic multi-zone heating plate. A thermal resistance layer 122 is arranged between the substrate heater 120 and baseplate 116. Baseplate 116 includes one or more coolant channels 124 for flowing coolant through baseplate 116. Substrate holder 104 further includes an edge ring 126 configured to encircle substrate 106.

The processing tool 100 further comprises a plasma generator 128 configured to generate a plasma in the processing chamber 102. The plasma generator 128 generates and outputs a radio frequency (RF) voltage to inner electrode 108 and outer electrode 110. In some examples, the RF voltage oscillates around a bias voltage. The conductive baseplate 116 can be direct current (DC) grounded, alternating current (AC) grounded, or floating. The plasma generator 128 includes an RF voltage generator 130 configured to generate the RF voltage. The RF voltage is supplied using an impedance matching and distribution network 132 to inner electrode 108 and outer electrode 110. In other examples, the plasma can be generated inductively, remotely, or using any other suitable method. Examples of plasma generator 128 comprise capacitively coupled plasma (CCP) systems, inductively coupled plasma (ICP) systems, and remote microwave plasma generation and delivery systems. In other examples, the RF voltage can be sent to the conductive baseplate 116, and inner electrode 108 and outer electrode 110 can be DC grounded, AC grounded, or floating.

A processing chemical delivery system 134 includes processing chemical sources 136A-136N (collectively processing chemical sources 136), where N indicates an arbitrary number of additional processing chemical sources that is equal to or greater than zero. As described in more detail below, processing chemical sources 136 supply an etching agent, a metal halide, and/or mixtures thereof. Vaporized precursors can be used in some examples. Processing chemical sources 136 can also supply an inert gas. Examples of inert gases include helium (He), neon (Ne), argon (Ar), krypton (Kr), xenon (Xe) and/or mixtures thereof.

The processing tool 100 further comprises flow control hardware 138. The flow control hardware 138 is configured to control a flow of each of one or more processing chemicals into the processing chamber 102. Each of the processing chemical sources 136 is in fluid communication with the flow control hardware 138. For example, processing chemical sources 136 are connected by valves 140A-140N (collectively valves 140) and mass flow controllers (MFCs) 142A-142N (collectively MFCs 142) to a manifold 144. As mentioned above, example processing chemical sources include an etching chemical source 136A and a metal halide source 136B. The processing chemical sources 136 optionally include one or more additional processing chemical sources 136N, such as an inert gas source. An output of manifold 144 is fed to processing chamber 102, for example via showerhead 112. Processing chemical delivery system 134 further can help to control a pressure of processing chamber 102.

A temperature controller 146 is connected to a plurality of thermal control elements (TCEs) 148 (e.g., heating elements) arranged in ceramic layer 118. Temperature controller 146 is used to control the TCEs 148 to control a temperature of substrate holder 104 and substrate 106. Further, temperature controller 146 communicates with a coolant assembly 150 to control coolant flow through coolant channels 124. In some examples, coolant assembly 150 can include a coolant pump and reservoir. Temperature controller 146 operates coolant assembly 150 to selectively flow the coolant through coolant channels 124 to cool substrate holder 104.

A valve 152 and a pump 154 can be used to evacuate reactants from processing chamber 102. Further, a system controller 156 is configured to control components of plasma processing tool 100. A robot 158 delivers substrates onto, and removes substrates from, substrate holder 104. For example, robot 158 transfers substrates between substrate holder 104 and a load lock 160. Although shown as separate controllers, temperature controller 146 can be implemented within system controller 156. Further, a protective seal 162 is provided around a perimeter of thermal resistance layer 122 between ceramic layer 118 and baseplate 116. In other examples, the protective seal 162 is omitted.

Processing chamber 102 further includes a plasma containment shroud 164. Plasma containment shroud 164 is arranged around outer electrode 110 and edge ring 126. In the depicted example, inner electrode 108, outer electrode 110, plasma containment shroud 164, and edge ring 126 confine the plasma within a plasma confinement area 166. In some examples, plasma containment shroud 164 is electrically connected to outer electrode 110 and inner electrode 108. Plasma containment shroud 164 includes one or more slots 168 to provide fluid communication between plasma confinement area 166 and an environment external to plasma containment shroud 164. In other examples, any other suitable plasma-exposed parts are used to confine a plasma within a plasma confinement area.

FIG. 1 is illustrative. In other examples, a processing tool can include any other components suitable for performing a plasma process. Other example components can include a remote plasma generation and delivery system. Further, in some examples, processing tool 100 can omit one or more components illustrated. While discussed herein in the context of a plasma etching tool, other processing tools can be used to implement the disclosed examples. Other examples of processing tools include PEALD and PECVD tools. Such tools can be configured to perform in-situ etching in some examples.

The processing tool 100 is configured to control the flow control hardware 138 to introduce a gas mixture into the processing chamber 102. The gas mixture comprises an etching agent from the etching chemical source 136A. An etching agent can be added to a plasma to produce reactive species to chemically react with and volatilize a surface of the substrate. Example etching agents include various chlorine-containing materials and fluorine-containing materials. Examples of chlorine-containing etching agents include molecular chlorine (Cl₂), nitrogen trichloride (NCl₃) boron trichloride (BCl₃), sulfur hexachloride (SCl₆), silicon tetrachloride (SiCl₄), and hydrogen chloride (HCl). Examples of fluorine-containing etching agents include molecular fluorine (F₂), nitrogen trifluoride (NF₃), boron trifluoride (BF₃), sulfur hexafluoride (SF₆), silicon tetrafluoride (SiF₄) and hydrogen fluoride (HF).

In some examples, the etching agent comprises a fluorocarbon. Some examples of fluorocarbons include, but are not limited to, fluorocarbon compounds having a general formula CₐH_{b}F_{c}, where a=1-10. Some more specific examples of fluorocarbons include fluoromethane (CH₃F), difluoromethane (CH₂F₂), trifluoromethane (CHF₃), tetrafluoromethane (CF₄), fluoroethane (C₂H₅F), and 1,1-difluoroethane (C₂H₄F₂). In some examples, such fluorinated compounds are used to etch silicon oxides or other metalloid oxides. In other examples, fluorinated compounds can be used to etch any other suitable material, such as titanium dioxide (TiO₂) or other metal oxides.

In other examples, the etching agent comprises a chlorocarbon. Some examples of chlorocarbons include, but are not limited to, chlorinated compounds having a general formula CₐH_{b}Cl_{c}, where a=1-10. Some more specific examples of chlorocarbons include chloromethane (CH₃Cl), dichloromethane (CH₂Cl₂), trichloromethane (CHCl₃), tetrachloromethane (CCl₄), chloroethane (C₂H₅Cl), and 1,1-dichloroethane (C₂H₄Cl₂). In some examples, such chlorinated compounds are used to etch metal oxides, such as TiO₂. In other examples, chlorinated compounds can be used to etch any other suitable material, such as metalloid oxides.

The gas mixture further comprises a metal halide from the metal halide source 136B. In some examples, the metal halide comprises a halide of one or more of silicon (Si), germanium (Ge), tin (Sn), titanium (Ti), zirconium (Zr), hafnium (Hf), vanadium (V), niobium (Nb), tantalum (Ta), boron (B), aluminum (Al), gallium (Ga), indium (In), iron (Fe), ruthenium (Ru), rhenium (Rh), antimony (Sb), tungsten (W), molybdenum (Mo), or bismuth (Bi). In some examples, the metal halide comprises a metal fluoride when the etching agent comprises a fluorocarbon. Some examples of metal fluorides include, but are not limited to, tungsten hexafluoride (WF₆) and molybdenum hexafluoride (MoF₆). In other examples, the metal halide comprises a metal chloride when the etching agent comprises a chlorocarbon. Some examples of metal fluorides include, but are not limited to, titanium tetrachloride (TiCl₄), tungsten hexachloride (WCl₆) and molybdenum pentachloride (MoCl₅). In yet other examples, the metal halide comprises an oxyhalide. Examples of oxyhalides include tungsten oxytetrafluoride (WOF₄), tungsten 1 oxytetrachloride (WOCl₄), molybdenum oxytetrafluoride (MoOₓF₄), and molybdenum oxytetrachloride (MoOₓCl₄). As described in more detail below, the metal halide and/or the etching agent react to form a substance containing a metal from the metal halide on a patterning mask.

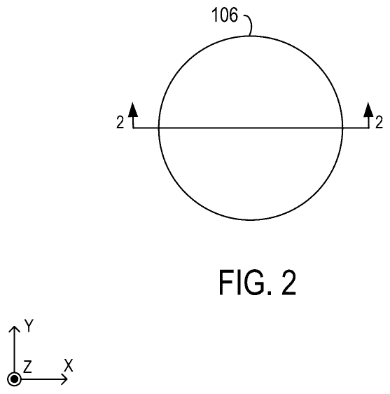

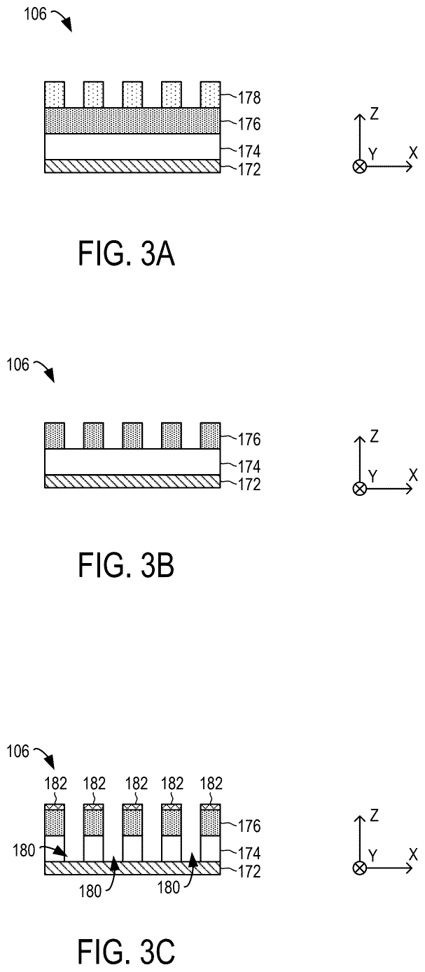

FIG. 2 shows a top-down view of the substrate 106 of FIG. 1. FIG. 3A shows a cross-sectional view of the substrate 106 along line 2-2 of FIG. 2. The substrate 106 comprises a layer 172 of arbitrary composition.

The substrate 106 further comprises an oxide layer 174 formed on layer 172. The oxide layer can include one or more layers of a doped or an undoped material. In some examples, the oxide layer comprises a metal oxide and/or a metalloid oxide. In some more specific examples, the oxide layer comprises silicon dioxide (SiO₂) and/or TiO₂. In other examples, the oxide layer comprises any other suitable material. Other examples of suitable materials include silicon oxynitride (SiOₓN_{y}, 0≤x≤2, 0≤y≤1.33), silicon oxycarbide (SiCₓO₂₍₁₋ₓ₎ (0≤x≤1)), hafnium oxide (HfOₓ), tungsten oxide (WOₓ), tin oxide (SnOₓ), molybdenum oxide (MoOₓ), and other oxides of titanium (TiOₓ).

A hard mask 176 covers the oxide layer 174. In some examples, the hard mask 176 comprises amorphous carbon. In other examples, the hard mask 176 comprises any other suitable material. Other examples of suitable materials include metal oxides, boron-doped carbon, tungsten-doped carbon, titanium nitride (TiN), silicon (Si), silicon nitride (Si₃N₄), silicon carbide (SiC), and xSi₃N₄·(1−x)SiC. As described in more detail below with reference to FIGS. 3B-3C, the hard mask 176 serves as a hard mask to transfer pattern features defined during a preliminary etch process into the oxide layer 174.

The substrate 106 of FIG. 3A further comprises a photoresist patterning mask 178. In some examples, the photoresist patterning mask 178 additionally includes a light-absorbing underlayer (not shown) configured to accelerate patterning of the photoresist layer 178. As described above, the photoresist patterning mask 178 selectively exposes portions of the hard mask 176. In this manner, material can be removed from the exposed portions of the hard mask 176 during a preliminary etching process. The photoresist patterning mask 178 protects unexposed portions of the hard mask 176 from the preliminary etching process. This results in pattern transfer from the photoresist patterning mask 178 to the hard mask 176, as described in more detail below with reference to FIG. 3B. It will also be appreciated that the shapes of the features etched in FIGS. 3A-3C are arbitrary, and the processes disclosed herein can be used with any suitable feature shape.

In some examples, the preliminary etching process is conducted in the processing tool 100. In other examples, the preliminary etching process is conducted prior to transferring the substrate 106 into the processing tool 100.

FIG. 3B shows the substrate 106 after the preliminary etching process. As illustrated in FIG. 3B, the exposed portions of the hard mask 176 are etched away. As a result, the oxide layer 174 is partially covered by the hard mask 176. As such, the hard mask 176 is a patterning mask for the oxide layer 174. This enables selective etching of the oxide layer 174.

Referring again to FIG. 1, the plasma generator 128 is used to generate a plasma in the processing chamber 102 to contemporaneously etch a feature 180 in an unmasked portion of the oxide layer 174 and deposit a substance containing a metal from the metal halide on the hard mask 176. In some examples, the feature 180 takes the form of a linear trench. In other examples, the feature 180 has any other suitable shape. Other examples of suitable features that can be formed include round holes, pillars, and spacers.

The plasma generator 128 is configured to apply RF power to transform the etching agent and the metal halide into a plasma. In some examples, the RF power is in a range of 20-1000 W. In some examples, the RF power is applied at a frequency in a frequency range of 400 kHz-60 MHz. In some more specific examples, the frequency is in a frequency range of 1-27 MHz. For example, the plasma generator 128 can operate at 13.56 MHz. In some examples, the plasma is generated with a processing chamber pressure of less than 1 Torr. In some more specific examples, the processing chamber is at a pressure in a range of 1-750 mTorr. In yet more specific examples, the processing chamber is at a pressure in a range of 2-500 mTorr. In some examples, the substrate 106 is maintained at a substrate temperature in a range of 0-300° C. during the etching process. In some more specific examples, the substrate temperature is in a range of 25-200° C. In yet more specific examples, the substrate temperature is in a range of 30-150° C.

The plasma selectively etches exposed portions of the oxide layer 174 and contemporaneously deposits a substance 182 containing a metal from the metal halide on the hard mask 176. The etching agent in the plasma reacts with the oxide layer 174 to etch the oxide layer. The etching agent in the plasma also reacts with the metal halide and the hard mask 176 to form the substance 182 on the hard mask 176. Equation (1) provides an example of a potential reaction between a metal halide (WF₆) and an etching agent (C₂F₄) at an amorphous carbon hard mask:

WF₆+C₂F₄+C_{(substrate)}->W+WCₓF_{y}+C_{(substrate)} (1)

The tungsten metal and WCₓF_{y} phases can increase the thickness of the amorphous carbon mask. Ion bombardment can further enhance plasma-resistance of the deposited film. Similar reactions can occur on other patterning masks. In contrast, solid phases may not form on an unmasked portion of an oxide layer being etched. Equation (2) provides an example of a potential reaction that occurs at an unmasked SiO₂ surface.

WF₆+C₂F₄+SiO₂->SiFₓ+WFₓ+CO₂ (2)

For example, the SiFₓ and WFₓ phases can be fully fluorinated during etching to form volatile SiF₄+WF₆. Other example volatile phases that can be formed include WOF₄. In some examples, the substance 182 additionally or alternatively includes a metal from the substrate 106. For example, Ti released while etching a TiO₂ layer can be incorporated into the substance 182 that deposits on the hard mask 176.

The use of the metal halide to deposit substance 182 on the hard mask 176 helps to avoid the hard mask 176 from being consumed during the etching process. In some examples, the substance 182 also helps the hard mask 176 resist degradation during ion bombardment. This may allow the use of a thinner \hard mask 176 than in etching processes that omit a metal halide as disclosed.

The substance 182 can be removed after etching the oxide layer 174. In some examples, a wet clean process is used to remove the substance 182 and the hard mask 176. Any suitable cleaning material can be used to remove the substance 182. Some examples of suitable cleaning materials include ammonia (NH₃) and hydrogen peroxide (H₂O₂).

In this manner, the oxide layer 174 can be patterned with higher fidelity than can be achieved in plasma etching processes that do not utilize the contemporaneous deposition of the substance containing the metal. Due to the additive deposition of the substance 182 on the hard mask 176, the hard mask 176 may achieve similar pattern-transfer fidelity than thicker hard mask materials, while avoiding defects such as line breakage, line roughness, and wiggling.

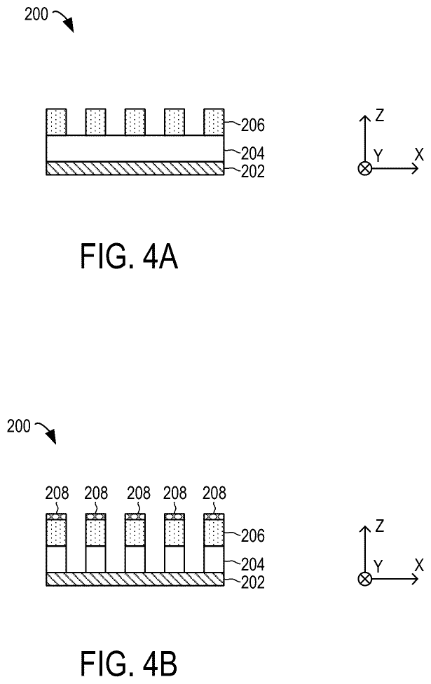

FIGS. 4A-4B show another example of a substrate 200. Like the substrate 106 of FIG. 1, the substrate 200 comprises a layer 202 of arbitrary composition. The substrate 200 further comprises an oxide layer 204 formed on layer 202. As described above, the oxide layer 204 may comprise any suitable material. Some examples of suitable materials include SiO₂, TiO₂, SiOₓN_{y} (0≤x≤2, 0≤y≤1.33), SiCₓO₂₍₁₋ₓ₎, (0≤x≤1), HfOₓ, WOₓ, SnOₓ, and MoOₓ.

The substrate 200 further comprises a photoresist patterning mask 206. The photoresist patterning mask 206 selectively exposes portions of the oxide layer 204. The exposed portions of the oxide layer 204 are selectively etched as described above using an etching agent and a metal halide. For example, the plasma generator 128 of FIG. 1 can be used as described above to transform the etching agent and the metal halide into a plasma. The plasma selectively etches the exposed portions of the oxide layer 204 and contemporaneously deposits a substance 208 containing a metal from the metal halide on the photoresist patterning mask 206. In this manner, the oxide layer 204 can be etched without additional hard mask deposition and patterning stages.

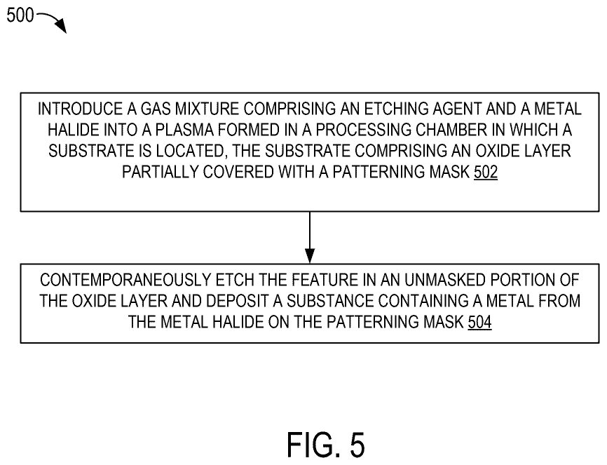

FIG. 5 shows a flow diagram depicting an example method 500 for etching a feature in an oxide layer formed on a substrate. The following description of the method 500 is provided with reference to the components described above and shown in FIGS. 1-4B and 9. It will be appreciated that the method 500 also can be performed in other contexts.

At 502, the method 500 comprises introducing a gas mixture comprising an etching agent and a metal halide into a plasma formed in a processing chamber in which a substrate is located, the substrate comprising an oxide layer partially covered with a patterning mask. For example, the processing tool 100 of FIG. 1 is configured to generate a plasma in the processing chamber 102 in which the substrate 106 is located.

In some examples, the etching agent comprises a fluorocarbon. Some examples of fluorocarbons include, but are not limited to, CH₃F, CH₂F₂, CHF₃, CF₄, C₂H₅F, and C₂H₄F₂. Further, in some examples, the etching agent additionally or alternatively comprises HF. Such etching agents react to remove material from the oxide layer.

In some examples, the oxide layer comprises a metal oxide or a metalloid oxide. In some such examples, the oxide layer comprises SiO₂ or TiO₂. As described above, other examples of suitable materials include, but are not limited to, SiOₓN_{y} (0≤x≤2, 0≤y≤1.33), SiCₓO₂₍₁₋ₓ₎ (0≤x≤1), HfOₓ, WOₓ, SnOₓ, and MoOₓ.

In some examples, the patterning mask comprises amorphous carbon. For example, the hard mask 176 of FIGS. 3A-3C can comprise amorphous carbon. Other examples of materials suitable for use in the patterning mask include metal oxides, amorphous carbon, boron-doped carbon, tungsten-doped carbon, TiN, Si, Si₃N₄, SiC, xSi₃N₄·(1−x)SiC, and polymer films.

The metal halide can comprise a halide of one or more of Si, Ge, Sn, Ti, Zr, Hf, V, Nb, Ta, B, Al, Ga, In, Fe, Ru, Rh, Sb, W, Mo, or Bi. In some such examples, the metal halide comprises one or more of WF₆ or MoF₆. In other examples, the metal halide comprises an oxyhalide. For example, the metal halide can include an oxygen atom and a halogen atom. The metal halide and/or the etching agent react with the patterning mask to deposit a substance containing a metal from the metal halide on the patterning mask.

The method 500 further comprises, at 504, contemporaneously etching the feature in an unmasked portion of the oxide layer and depositing the substance containing a metal from the metal halide on the patterning mask. For example, the etching agent in the plasma reacts with the oxide layer to etch the oxide layer. The etching agent in the plasma also reacts with the metal halide and carbon atoms in the patterning mask to form the substance on the patterning mask.

Thus, etching a feature in an oxide layer as disclosed maintains or increases a thickness of a patterning mask (e.g., a hard mask or a photoresist patterning mask) during the etching process. As described above, an etching agent and a metal halide are introduced into the processing chamber. The metal halide and/or the etching agent react with the patterning mask to form a substance containing a metal from the metal halide. This substance selectively deposits on the patterning mask during the etching process. The substance protects the patterning mask from degradation. As a result, the etching process disclosed herein transfers pattern features to the oxide layer with more fidelity than etching processes that lack additive deposition on a mask layer. By preventing degradation of the patterning mask, the disclosed etching process can also prevent manufacturing defects such as line breakage, line roughness, and wiggling.

In an EUV (extreme ultraviolet) photoresist patterning process that utilizes a metal oxide photoresist (e.g. an organo-tin oxide resist), some residual undesired photoresist material may remain on the substrate after development. This material can be referred to as mask remnants, or scum. Mask remnants can impact the accuracy of subsequent pattern transfer. Therefore, to help ensure accurate pattern transfer, the mask remnants can be removed from the substrate in a descum process prior to performing etching for transfer of the photoresist pattern to one or more underlying layers. However, the process of removing the mask remnants can potentially impact the photoresist patterning mask.

Thus, to help protect a photoresist patterning mask from degradation during mask remnant removal, a metal halide can be used to deposit a protective layer of a substance comprising the metal from the metal halide on the photoresist patterning mask. In some examples, the protective layer can be deposited during the mask remnant removal process by introducing a metal halide during the mask remnant removal process. Alternatively or additionally, the protective layer can be deposited in a separate step prior to performing the mask remnant removal process. As described above, the metal halide can react with carbon to deposit an additive material. Metal oxide EUV resists (e.g. tin oxide-based resists) can include carbon-containing ligands (e.g. alkyl ligands) bonded to the metal atoms. The carbon in the photoresist material can react with the etching agent and the metal halide in the plasma to form the additive material, for example, as shown above in equation (1). In this manner, the photoresist patterning mask can be protected before or during the mask remnant removal process. This can help to preserve the accuracy of the pattern transfer to one or more underlying layers.

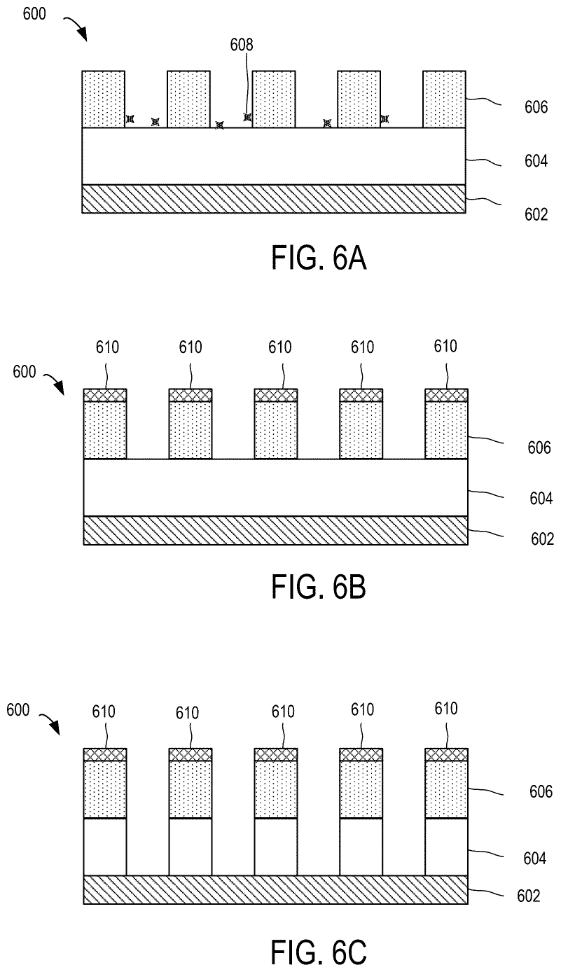

FIGS. 6A-6C illustrate an example process for removing mask remnants while protecting a photoresist patterning mask with a layer of a substance formed using a metal halide. First, FIG. 6A shows an example substrate 600. The substrate 600 comprises a layer 602 of arbitrary composition. The substrate 600 further comprises a hard mask layer 604 formed on layer 602. As described above, the hard mask layer 604 comprises carbon (e.g. amorphous carbon or diamond-like carbon). Other examples of suitable materials for the hard mask layer 604 include boron-doped carbon, tungsten-doped carbon, silicon carbide (SiC), and xSi₃N₄·(1−x)SiC. The substrate 600 further comprises a metal oxide-based photoresist patterning mask 606 formed on the hard mask layer 604 for transferring a pattern to the hard mask layer 604. The photoresist patterning mask 606 is shown after development, and thus has mask remnants 608.

During the mask remnant removal process, substrate 600 is exposed to an inert plasma, such as a helium plasma. Energetic ions from the plasma impact the mask remnants and cause desorption of the mask remnants from the substrate. However, the energetic ions also can cause damage to the photoresist patterning mask. To help reduce damage caused by the mask remnant removal process, a metal halide can be introduced into a plasma to form a protective layer of a substance containing the metal from the metal halide, either before or during the mask remnant removal plasma process. The metal from the metal halide can react with the carbon in the photoresist patterning mask to deposit the substance on the photoresist patterning mask. FIG. 6B shows the substrate 600 after performing deposition of a substance 610 on the photoresist patterning mask 606 and a mask remnant removal process.

Concentrations of the metal halide and/or plasma conditions can be selected to help avoid deposition of the substance 610 on the mask remnants. For example, referring briefly again to FIG. 6A, the mask remnants 608 are primarily located on sidewalls of the photoresist patterning mask 606, and on hard mask layer 604. Thus, a concentration of the metal halide can be selected such that the metal halide is consumed primarily closer to top surfaces of the photoresist patterning mask 606 than deeper within the pattern formed by the photoresist patterning mask 606.

FIG. 6C shows an example of the substrate 600 after plasma etching the hard mask layer 604. In some examples, the plasma comprises an etching agent (e.g. an oxygen-containing or hydrogen-containing etching agent) and a metal halide plasma, as described above. In such examples, the layer of the substance 610 can be thickened by further deposition of the substance 610 during the etching process. In other examples, the plasma comprises the etching agent but omits the metal halide. In such examples, the layer of the substance 610 formed during the mask remnant removal process can be used to protect the photoresist patterning mask 606 during pattern transfer to the hard mask layer 604.

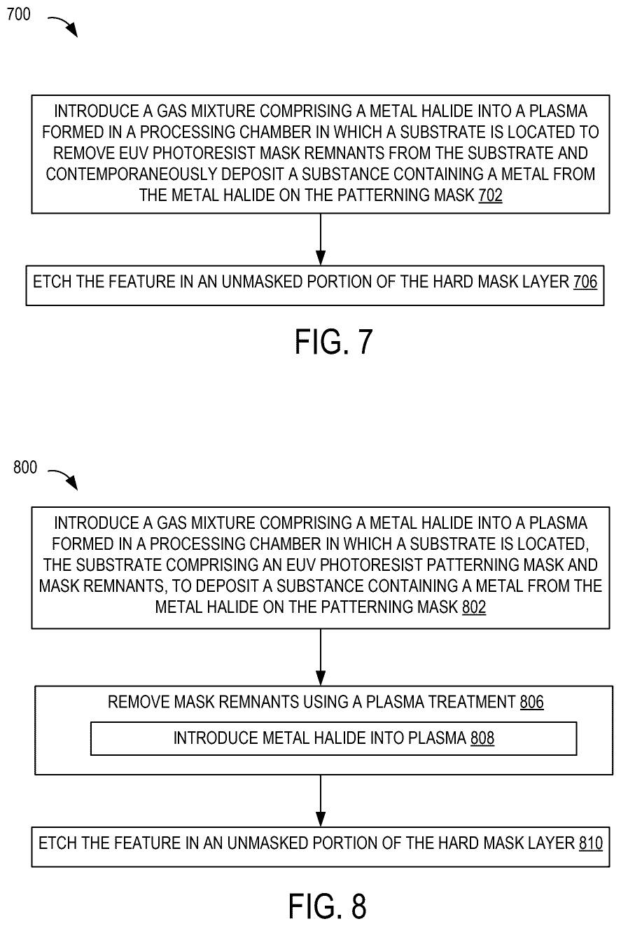

FIG. 7 shows a flow diagram depicting an example method 700 in which the removal of the patterning mask remnants and deposition of the substance containing a metal from the metal halide occurs contemporaneously. The following description of the method 700 is provided with reference to the components described above and shown in FIGS. 6A-6C. It will be appreciated that the method 700 also can be performed in other contexts.

At 702, the method 700 comprises introducing a gas mixture comprising an inert gas and the metal halide into a plasma formed in the processing chamber. The processing chamber comprises a substrate with a hard mask layer, an EUV photoresist patterning mask, and mask remnants on the hard mask layer. The mask remnants are remnants from the EUV photoresist development process. The EUV photoresist patterning mask is configured to transfer a pattern to the hard mask layer. In some examples, the hard mask layer comprises carbon, such as amorphous carbon or diamond-like carbon. In other examples, the hard mask 604 comprises another other suitable material, including those described above. Energetic inert gas ions in the plasma can remove the mask remnants by transferring kinetic energy to the mask remnants to cause desorption.

The metal halide is configured to deposit a substance containing the metal on the patterned EUV photoresist layer by reacting with carbon in the photoresist. As mentioned above, some examples of the metal halide include halides of silicon (Si), germanium (Ge), tin (Sn), titanium (Ti), zirconium (Zr), hafnium (Hf), vanadium (V), niobium (Nb), tantalum (Ta), boron (B), aluminum (Al), gallium (Ga), indium (In), iron (Fe), ruthenium (Ru), rhenium (Rh), antimony (Sb), tungsten (W), molybdenum (Mo), or bismuth (Bi). As more specific examples, the metal halide can include one or more of tungsten hexafluoride (WF₆), molybdenum hexafluoride (MoF₆), titanium tetrachloride (TiCl₄), tungsten hexachloride (WCl₆), molybdenum pentachloride (MoCl₅), as well as oxyhalides, such as tungsten oxytetrafluoride (WOF₄), tungsten oxytetrachloride (WOCl₄), molybdenum oxytetrafluoride (MoOₓF₄), or molybdenum oxytetrachloride (MoOₓCl₄). The metal halide can react with the carbon in the photoresist to deposit the layer of the substance containing the metal onto the photoresist patterning mask.

Removal of the mask remnants allows for the more accurate transfer of the EUV photoresist mask pattern to the hard mask layer in comparison to processes when mask remnant removal is omitted. Further, the substance containing the metal helps to protect the EUV photoresist patterning mask during the mask remnant removal step, further ensuring accurate pattern transfer.

After removing the mask remnants, the method 700 further comprises, at 706, etching the unmasked portion of the hard mask layer, thereby transferring the EUV photoresist patterning mask pattern to the hard mask layer. As mentioned above, the etching agent can utilize an oxygen-containing or hydrogen-containing etching agent.

FIG. 8 shows a flow diagram depicting an example method 800 in which the deposition of the substance containing a metal from the metal halide and the removal of the EUV photoresist patterning mask remnants occur sequentially. At 802, the method 800 comprises introducing a gas mixture comprising the metal halide into a plasma formed in a processing chamber. The processing chamber comprises a substrate with a hard mask layer, and an EUV photoresist patterning mask and mask remnants on the hard mask layer.

As described above, the metal halide is configured to deposit a substance containing the metal on the patterned photoresist mask by reacting with carbon in the photoresist. Example metal halides include those listed above.

The substance containing the metal deposited onto the photoresist patterning mask acts as a protection layer, and helps to protect the mask from degradation during the mask remnant removal step. This can help to achieve more accurate pattern transfer than where the metal halide is not used.

The method 800 further comprises removing the mask remnants at step 806. As described above, an inert plasma can be used to remove the mask remnants by desorption using energetic ions. Removal of the mask remnants allows for the more accurate transfer of the mask pattern to the hard mask layer in comparison to processes when mask remnant removal is omitted. During the mask remnant removal step 806, the substance containing the metal deposited onto the EUV photoresist patterning mask in step 802 acts as a protection layer, as mentioned above.

In some examples, as indicated at 808, the mask remnant removal step 806 includes introducing a metal halide into the plasma. In such examples, deposition of the substance containing a metal from the metal halide further occurs both before and contemporaneously with the removal of patterning mask remnants. As described above, the metal halide can react with the carbon in the photoresist patterning mask to form a protection layer. This can help to further protect the photoresist patterning mask while performing the mask remnant removal step. Examples of the metal halide include those listed above. In other examples, the metal halide is omitted from the mask remnant removal step. After the sequential removal of the mask remnants and the formation of the protection layer in 806 and 808, the method 800 further comprises, at 810, etching the pattern into an unmasked portion of the hard mask layer, as described above with regard to FIG. 7.

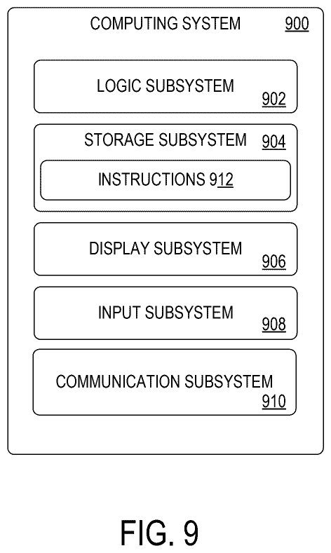

FIG. 9 schematically shows a non-limiting example of a computing system 900 that can enact one or more of the methods and processes described above. Computing system 900 is shown in simplified form. Computing system 900 can take the form of one or more personal computers, workstations, computers integrated with substrate processing tools, and/or network accessible server computers.

Computing system 900 includes a logic subsystem 902 and a storage subsystem 904. Computing system 900 can optionally include a display subsystem 906, input subsystem 908, communication subsystem 910, and/or other components not shown in FIG. 9. System controller 156 is an example of computing system 900.

Logic subsystem 902 includes one or more physical devices configured to execute instructions. For example, the logic subsystem can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result.

The logic subsystem can include one or more processors configured to execute software instructions. Additionally or alternatively, the logic subsystem can include one or more hardware or firmware logic subsystems configured to execute hardware or firmware instructions. Processors of the logic subsystem can be single-core or multi-core, and the instructions executed thereon can be configured for sequential, parallel, and/or distributed processing. Individual components of the logic subsystem optionally can be distributed among two or more separate devices, which can be remotely located and/or configured for coordinated processing. Aspects of the logic subsystem can be virtualized and executed by remotely accessible, networked computing devices configured in a cloud-computing configuration.

Storage subsystem 904 includes one or more physical devices configured to hold instructions 912 executable by the logic subsystem to implement the methods and processes described herein. When such methods and processes are implemented, the state of storage subsystem 904 can be transformed—e.g., to hold different data.

Storage subsystem 904 can include removable and/or built-in devices. Storage subsystem 904 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 904 can include volatile, nonvolatile, dynamic, static, read/write, read-only, random-access, sequential-access, location-addressable, file-addressable, and/or content-addressable devices.

It will be appreciated that storage subsystem 904 includes one or more physical devices. However, aspects of the instructions described herein alternatively can be propagated by a communication medium (e.g., an electromagnetic signal, an optical signal, etc.) that is not held by a physical device for a finite duration.

Aspects of logic subsystem 902 and storage subsystem 904 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 906 can be used to present a visual representation of data held by storage subsystem 904. This visual representation can take the form of a graphical user interface (GUI). As the herein described methods and processes change the data held by the storage subsystem, and thus transform the state of the storage subsystem, the state of display subsystem 906 can likewise be transformed to visually represent changes in the underlying data. Display subsystem 906 can include one or more display devices utilizing virtually any type of technology. Such display devices can be combined with logic subsystem 902 and/or storage subsystem 904 in a shared enclosure, or such display devices can be peripheral display devices.

When included, input subsystem 908 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition, and an infrared, color, stereoscopic, and/or depth camera for machine vision and/or gesture recognition.

When included, communication subsystem 910 can be configured to communicatively couple computing system 900 with one or more other computing devices. Communication subsystem 910 can include wired and/or wireless communication devices compatible with one or more different communication protocols. As non-limiting examples, the communication subsystem can be configured for communication via a wireless telephone network, or a wired or wireless local- or wide-area network. In some examples, the communication subsystem can allow computing system 900 to send and/or receive messages to and/or from other devices via a network such as the Internet.

This disclosure is presented by way of example and with reference to the associated drawing figures. Components, process steps, and other elements that can be substantially the same in one or more of the figures are identified coordinately and are described with minimal repetition. It will be noted, however, that elements identified coordinately can also differ to some degree. It will be further noted that some figures can be schematic and not drawn to scale. The various drawing scales, aspect ratios, and numbers of components shown in the figures can be purposely distorted to make certain features or relationships easier to see.

“And/or” as used herein is defined as the inclusive or V, as specified by the following truth table:

| A | B | A ∨ B |
|---|---|---|
| True | True | True |
| True | False | True |
| False | True | True |
| False | False | False |

The terminology “one or more of A or B” as used herein comprises A, B, or a combination of A and B. The terminology “one or more of A, B, or C” is equivalent to A, B, and/or C. As such, “one or more of A, B, or C” as used herein comprises A individually, B individually, C individually, a combination of A and B, a combination of A and C, a combination of B and C, or a combination of A, B and C.

It will be understood that the configurations and/or approaches described herein are exemplary in nature, and that these specific embodiments or examples are not to be considered in a limiting sense, because numerous variations are possible. The specific routines or methods described herein can represent one or more of any number of strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of etching a feature in an oxide layer on a substrate, the method comprising:
introducing a gas mixture comprising an etching agent and a metal halide into a plasma formed in a processing chamber in which the substrate is located, the substrate comprising a patterning mask partially covering the oxide layer; and
contemporaneously etching the feature in an unmasked portion of the oxide layer and depositing a substance containing a metal from the metal halide on the patterning mask.

2. The method of claim 1, wherein the etching agent comprises a fluorocarbon.

3. The method of claim 1, wherein the etching agent comprises hydrogen fluoride.

4. The method of claim 1, wherein the oxide layer comprises a metal oxide or a metalloid oxide.

5. The method of claim 1, wherein the oxide layer comprises silicon dioxide or titanium dioxide.

6. The method of claim 1, wherein the patterning mask comprises one or more of a metal oxide, amorphous carbon, boron-doped carbon, tungsten-doped carbon, titanium nitride, silicon, silicon nitride, silicon carbide, silicon carbonitride, or a photoresist material.

7. The method of claim 1, wherein the metal halide comprises a halide of one or more of silicon, germanium, tin, titanium, zirconium, hafnium, vanadium, niobium, tantalum, boron, aluminum, gallium, indium, iron, ruthenium, rhenium, antimony, tungsten, molybdenum, or bismuth.

8. The method of claim 1, wherein the metal halide comprises one or more of tungsten hexafluoride or molybdenum hexafluoride.

9. The method of claim 1, wherein the metal halide comprises an oxyhalide.

10. A processing tool, comprising:
a processing chamber;
a plasma generator configured to generate a plasma in the processing chamber;
a substrate holder positioned within the processing chamber;
flow control hardware configured to control a flow of each of one or more processing chemicals into the processing chamber; and
a controller configured to
control the flow control hardware to introduce a gas mixture comprising an etching agent and a metal halide into the processing chamber; and
control the plasma generator to generate the plasma in the processing chamber, wherein the gas mixture and the plasma are configured to etch an unmasked oxide layer on a substrate, and contemporaneously deposit a substance containing a metal from the metal halide on a masked portion of the substrate comprising a patterning mask that covers a portion of the oxide layer.

11. The processing tool of claim 10, further comprising an etching chemical source wherein the etching chemical source comprises a fluorocarbon.

12. The processing tool of claim 10, further comprising an etching chemical source wherein the etching chemical source comprises hydrogen fluoride.

13. The processing tool of claim 10, further comprising a metal halide source, wherein the metal halide source comprises a halide of one or more of silicon, germanium, tin, titanium, zirconium, hafnium, vanadium, niobium, tantalum, boron, aluminum, gallium, indium, iron, ruthenium, rhenium, antimony, tungsten, molybdenum, or bismuth.

14. The processing tool of claim 13, wherein the metal halide source comprises an oxyhalide.

15. A method of removing patterning mask remnants from a substrate between a resist development process and an etching process, the method comprising:
introducing a metal halide into a plasma formed in a processing chamber in which the substrate is located, the substrate comprising a photoresist patterning mask and patterning mask remnants, to deposit a substance containing a metal from the metal halide at least on the photoresist patterning mask to protect the photoresist patterning mask during removal of the patterning mask remnants.

16. The method of claim 15, wherein the photoresist patterning mask comprises a metal oxide photoresist.

17. The method of claim 15, wherein the removal of the patterning mask remnants and deposition of the substance containing a metal from the metal halide occurs contemporaneously.

18. The method of claim 15, wherein the deposition of the substance containing a metal from the metal halide and the removal of the patterning mask remnants occur sequentially.

19. The method of claim 15, wherein the substrate comprises a hard mask layer beneath the photoresist patterning mask.

20. The method of claim 15, wherein deposition of the substance containing a metal from the metal halide further occurs both before and contemporaneously with the removal of patterning mask remnants.
